(19) United States
(12) Patent Application Publication
(10) Pub. No.: US 2003/0201121 A1
(43) Pub. Date: Oct. 30, 2003

(54) Method of solving the unlanded phenomenon of the via etch

(76) Inventor: Pei-Ren Jeng, Hsinchu (TW)

Correspondence Address: STOUT, UXA, BUYAN & MULLINS LLP, 4 VENTURE, SUITE 300, IRVINE, CA, 92618, US

(21) Appl. No.: 10/132,423

(22) Filed: Apr. 25, 2002

(51) Int. Cl. H05K 1/03

(52) U.S. Cl. 174/256

(57) ABSTRACT

Dyed SOG is used as a rapid-etch material to minimize problems associated with unlanded via that are typically caused by via-mask misalignment. A thin barrier layer of anti-reflective coating (ARC) is disposed between the rapid-etch material and an underlying metal layer. The rapid-etch material, the ARC layer, and the metal layer are all etched back to yield multiple thin metal lines, and these metal lines are then blanketed with a HDP deposited layer. Subsequently, via holes are etched into both the HDP deposited layer and the rapid-etch material using an etchant which is more reactive with the rapid-etch material than the HDP deposited layer.

### BACKGROUND OF THE INVENTION

1. Field of the Invention

The present invention relates generally to semiconductor fabrication methods and, more particularly, to methods for fabricating landed and unlanded via.

2. Description of Related Art

A seemingly insatiable desire for augmenting speeds and capacities in connection with semiconductor circuits continues to fuel the industry-wide movement toward greater device performances and densities. In seeking to achieve these ends, one approach has been to generate on-chip device architectures having multiple conductive layers. Within a semiconductor circuit structure, these multiple conductive layers are typically connected to one another through the use of via. A via is an opening formed in an interlayer dielectric that is filled with a conductive material, for the facilitation of an electrical interconnection between the multiple conductive layers. Such multiple conductive layers, which typically comprise metallic layers, are commonly separated by interlayer dielectrics in efforts to attenuate or eliminate cross-talk and leakage between semiconductor devices.

A problem typically encountered during the fabrication of via between multiple conductive layers is that of misalignment, which occurs when a photoresist mask implemented in the formation of the via does not accurately or completely overlay the desired structures. This misalignment of the photoresist mask with the desired structures can create a problematic structure known as an unlanded via. An unlanded via is one that rests partially on and partially off of a metallic line with which the via is to establish contact, while a landed via has formed an adequate contact with the metallic line.

One measure implemented in the prior art for preventing problems associated with photoresist-mask misalignment during via hole etching is to incorporate enlarged electrode pads onto the metallic lines, wherein diameters of the enlarged electrode pads are greater than diameters of the metallic lines and the via. The enlarged electrode pads thus operate to prevent the occurrence of unlanded via, even when misalignments between the via and the enlarged electrode pads are present. However, these landed conditions of the via are not achieved without sacrifice, since the enlarged electrode pads can increase the space required for each via and can increase separation distances between the metallic lines. Both of these dimensional limitations can hinder optimal movement of the industry toward increased densities of integrated circuits and devices.

On the other hand, relatively dense packing can be facilitated when the via are positioned directly onto the metallic lines, as distinguished from being positioned on enlarged electrode pads, but this advantage is obtained at the expense of increasing the probabilities of generating unlanded via. Prior-art attempts to position via directly onto the metallic lines have included the basic steps of mask etching down to a metallic line buried in a silicon oxide, and filling the etched formations with a via filler material to yield the via. When the etching step occurs with a misaligned photoresist mask, these etches can extend beyond the edges of the metallic lines resulting in unlanded via.

In the case of unlanded via, portions or adverse structures of the via that are disposed partially off of the metallic lines can extend down beneath the surface level of the metallic lines. The sides of the metallic lines beneath this surface level can consequently be exposed. These adverse structures, extending beneath the surface level of the metallic lines, will typically have a high aspect ratio. The filling of these adverse structures with a via filler material during a following processing step can become increasingly difficult, with increasingly higher and higher aspect ratios. Even after the via holes have been filled, small air gaps can remain in high aspect-ratio adverse formations. Accordingly, unlanded via can introduce poor connections between metal layers, can trap impurities, and can create parasitic electrical resistance between layers. Moreover, poor via contacts can be a significant mode of failure among submicron devices.

A need thus exists in the prior art to minimize the formation of problematic unlanded via for proper circuit interconnections and reduced resistances. A further need exists for processing methods and resulting constructions that can generate proper via contacts with the metal layers, even when photoresist-mask misalignment conditions are prevalent.

### SUMMARY OF THE INVENTION

The present invention addresses these needs by providing methods of manufacturing via and the resulting via that are less susceptible to the formation of poor electrical contacts, which have commonly occurred as a result of photoresist-mask misalignment. The invention herein disclosed attenuates and preferably eliminates the occurrence of unlanded-via adverse structures which can extend to the sides of the metallic lines and generate small air gaps.

The invention disclosed herein provides a rapid-etch layer comprising a rapid-etch material, which is used in place of conventional materials such as silicon-oxy-nitride (SiON). The rapid-etch material, which can comprise, for example, spin on glass (SOG) or dyed SOG, is disposed above a conductive (e.g., metal) layer. In accordance with one aspect of the invention, between the rapid-etch material and the metal layer is an optional thin layer of anti-reflective coating (ARC), such as titanium nitride (TiN). The rapid-etch material, the ARC layer, and the metal layer are all etched back as a result of a lithography step to leave a multitude of thin metal lines, and these metal lines are blanketed with another dielectric layer, such as a HDP deposited layer.

In accordance with a method of the present invention, chemical mechanical planarization (CMP) can be used to planarize the HDP deposited layer, before a lithography step is implemented to etch the HDP deposited layer and the rapid-etch material to thereby generate at least one via hole over the metal lines. Even if the via hole suffers from the unlanded phenomenon, the side walls of the metal lines are not revealed as a result of the rapid-etch material etching faster than the HDP layer. A via filler such as tungsten is subsequently used to plug the via hole to form a via. In another aspect of the present invention, the rapid-etch material may comprise SOG as a substitute for the dyed SOG. In accordance with an alternative aspect of the invention, SOG or dyed SOG may also be used as a hard mask during the above-mentioned etch process of the metal layer to yield the thin metal lines, thus allowing for a thinner photoresist layer.

A method in accordance with one aspect of the invention comprises the steps of providing a substrate with a conductive layer and an optional ARC layer formed thereon, depositing a rapid-etch dielectric layer on the ARC layer, and then defining a plurality of conductive lines in association with a first etching step. Another dielectric layer is then deposited, and at least one via hole is defined in association with a second etching step in which the rapid-etch dielectric layer is etched at a higher rate than a rate at which the other dielectric layer is etched.

An etching-rate characteristic of the rapid-etch dielectric layer on top of the ARC layer can be greater than an etching-rate characteristic of the other dielectric layer. In accordance with another aspect the second etching step is performed with an etchant and an etching rate of the rapid-etch dielectric layer to the etchant is greater than an etching rate of the other dielectric layer to the etchant. The step of depositing a rapid-etch dielectric layer can comprise a step of depositing a spin on glass (SOG) layer on the optional ARC layer, and in certain aspects of the invention the SOG layer can comprise dyed SOG. If a dyed SOG is used then the ARC layer may be omitted, in which case reference to the ARC layer herein can be construed as references to the conductive layer. The other dielectric layer can comprises a dielectric layer formed by high density plasma (HDP) chemical vapor deposition (CVD), the conductive layer can comprise a metallic layer, and the plurality of conductive lines can comprises a plurality of metallic lines.

In accordance with yet another aspect of the present invention, a structure comprises a plurality of conductive lines extending on covered portions of a substrate but not extending on uncovered portions of the substrate, a rapid-etch material positioned over regions of the plurality of conductive lines, a dielectric material disposed over at least parts of the covered portions and the uncovered portions, and at least one via hole etched into the dielectric material using an etchant, wherein an etching rate of the rapid-etch material for the etchant is greater than an etching rate of the dielectric material for the etchant. The rapid-etch material can be positioned on the regions of the plurality of conductive lines, and the dielectric material can be disposed above parts of the covered portions and on the uncovered portions. Moreover, the structure can comprise a plurality of optional anti-reflective coating (ARC) lines disposed on the plurality of conductive lines, the at least one via hole con comprise a plurality of via holes, and the plurality of via holes can be disposed on first regions of the ARC lines. The rapid-etch material can thus comprise a dielectric material disposed on second regions of the ARC lines, wherein the first regions of the ARC lines are not the same as the second regions of the ARC lines.

According to a further aspect of the present invention, a structure comprises a substrate and a plurality of conductive lines extending within corresponding first boundaries of the substrate but not extending within second boundaries of the substrate. At least one via hole overlaps both one of the first boundaries and one of the second boundaries, wherein a part of the at least one via hole overlapping the second boundary does not extend in a direction toward the substrate as far as a part of the at least one via hole overlapping the first boundary. In one aspect, the at least one via hole comprises a plurality of via holes overlapping corresponding first and second boundaries, wherein each of the via holes is filled with a conductive material, which can comprise tungsten, to form a via. In certain aspects of the invention, the structure can further comprise a rapid-etch material disposed over at least parts of the plurality of conductive lines, and in additional aspects the rapid-etch material can cover portions of the plurality of conductive lines that exclude the first boundaries overlapped by the plurality of via holes.

The structure can further comprise a plurality of optional ARC lines disposed on the plurality of conductive lines, wherein the plurality of ARC lines are at least partially sandwiched between the plurality of via and the plurality of conductive lines. Furthermore, a rapid-etch material can be disposed on portions of the plurality of ARC lines. In accordance with another aspect, the rapid-etch material can cover portions of the plurality of ARC lines which exclude the first boundaries overlapped by the plurality of via holes.

According to a further aspect of the present invention, a structure comprises a substrate having at least one conductive line disposed thereon, at least one optional ARC line disposed on the at least one conductive line, a rapid-etch material disposed over a first portion of the at least one ARC line, and at least one via hole disposed over a second portion of the at least one ARC line. The first portion of the at least one ARC line is not the same as the second portion of the at least one ARC line, and the at least one via hole does not extend, in a direction toward the substrate, beneath an upper surface of the at least one ARC line. In one configuration the at least one via hole does not extend, in a direction toward the substrate, beneath the at least one ARC line and in another configuration the at least one via hole does not contact the at least one conductive line. According to another aspect of the present invention, the at least one conductive line comprises a plurality of conductive lines, the at least one optional ARC line comprises a plurality of optional ARC lines, the at least one via hole comprises a plurality of via holes, the first portion of the at least one ARC line comprises a plurality of first portions of a corresponding plurality of ARC lines, and the second portion of the at least one ARC line comprises a plurality of second portions of a corresponding plurality of ARC lines.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE FIGURES

FIG. 1 is a perspective view of conventional, off-center via in contact with enlarged electrode pads, which are disposed at the ends of metallic lines;

FIG. 2 is a perspective view of conventional unlanded via in partial contact with metallic lines;

FIG. 3 is a cross-sectional view of prior-art metallic lines disposed on a silicon wafer, the metallic lines being separated by a high density plasma (HDP) deposited dielectric layer and partially covered by a layer of patterned photoresist;

FIG. 4 is a cross-sectional view of the prior-art wafer of FIG. 3 in which the HDP layer has been etched, the photoresist has been removed, and the via holes have been filled;

FIG. 5 is a cross-sectional view similar to the prior-art configuration illustrated in FIG. 4, wherein the patterned photoresist is misaligned;

FIG. 6 is a cross-sectional view of the prior-art wafer of FIG. 5 after etching and filling of the via holes, wherein the resulting via are unlanded;

FIG. 7 is a cross-sectional view of a multilayer film stack disposed on a silicon substrate for processing in accordance with an embodiment of the present invention;

FIG. 8 is a cross-sectional view of the configuration illustrated in FIG. 7 in which a patterned photoresist layer is disposed over a dyed spin on glass (SOG) layer in accordance with a presently preferred embodiment of the invention;

FIG. 9 is a cross-sectional view of the configuration illustrated in FIG. 8 in which the film stack has been mask etched down to the substrate in accordance with the present invention;

FIG. 10 is a cross-sectional view of the configuration of FIG. 9 in which the photoresist layer has been removed in accordance with the present invention;

FIG. 11 is a cross-sectional view showing the configuration of FIG. 10 with the addition of a HDP deposited layer according to an embodiment of the present invention;

FIG. 12 is a cross-sectional view of the configuration of FIG. 11 in which the HDP deposited layer has been planarized and a patterned photoresist layer has been added according to an embodiment of the present invention;

FIG. 13 is a cross-sectional view of the configuration illustrated in FIG. 12 in which a selective etching process has been accomplished in accordance with a presently preferred embodiment of the invention;

FIG. 14 is a cross-sectional view showing unlanded via holes which have been plugged with a via filler in accordance with the present invention; and

FIG. 15 is a flow chart showing a process flow of a preferred embodiment of the present invention.

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed cover all modifications, alternatives, and equivalents of the embodiments as may fall within the spirit and scope of the invention as defined by the appended claims. For example, it is understood by a person of ordinary skill practicing this invention that the via fabricated in accordance with the present invention are formed through a selective etch process, wherein a rapid-etch layer over each metallic line has an etching rate to an etchant that is greater than an etching rate (to the same etchant) of the dielectric separating the metallic lines. Hence, when the photoresist mask is misaligned with the metallic lines, the via holes are still selectively etched primarily only over the metallic lines and not to the sides of the metallic lines. Different rapid-etch materials, different dielectrics, different etchants, and different combinations thereof, can thus be implemented in accordance with the present invention, so long as the via holes are etched primarily over, and not to the sides of and beneath, the metallic lines.

It is to be understood and appreciated that the process steps and structures described herein do not cover a complete process flow for the manufacture of via. The present invention may be practiced in conjunction with various integrated circuit fabrication techniques that are conventionally used in the art, and only so much of the commonly practiced process steps are included herein as are necessary to provide an understanding of the present invention.

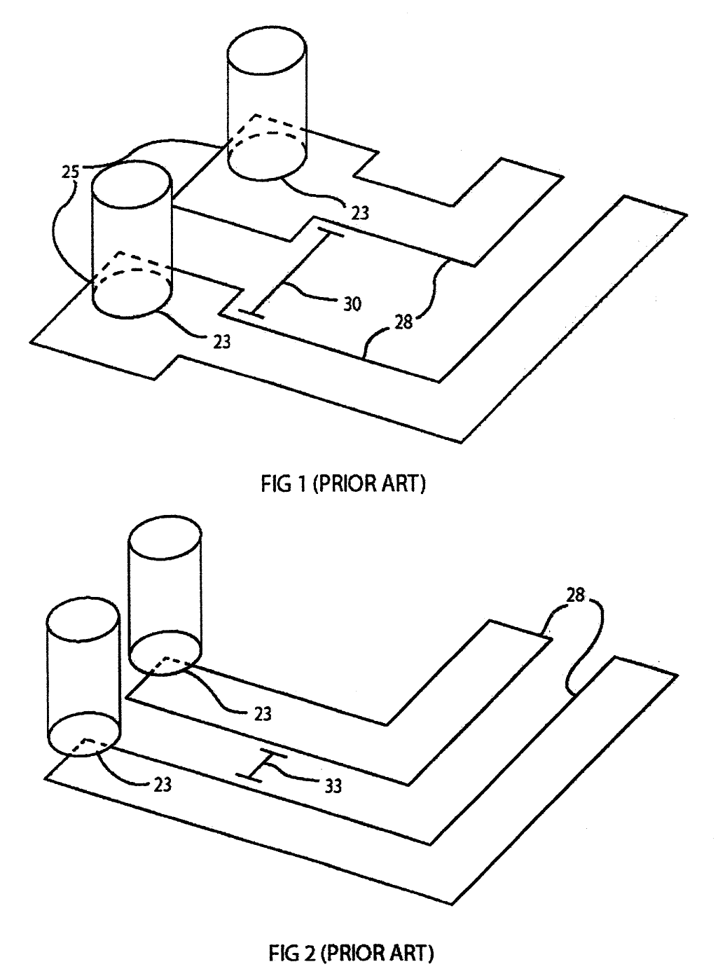

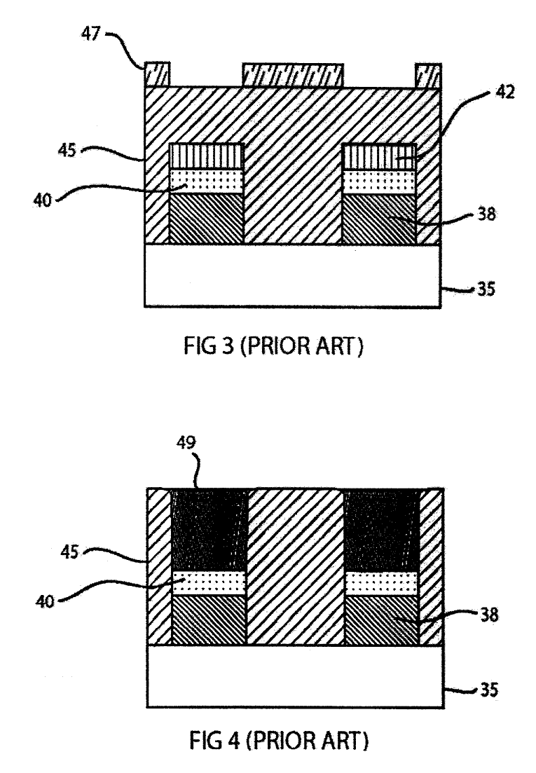

Referring more particularly to the drawings, FIG. 1 illustrates a prior-art configuration of two via 23 disposed in an off-center fashion on a corresponding pair of enlarged electrode pads 25. Ideally, each of the via 23 would be centered on a respective one of the enlarged electrode pads 25. The misalignment condition shown in FIG. 1 can originate with an inaccurate placement of a photoresist mask, such as mask 47 (FIG. 3), during an etching process. This resulting shifted orientation of the photoresist mask is then transferred to the photoresist being etched and, subsequently, transferred to the location and alignment of the via 23. However, despite the misalignment of the via 23, they are still in fill electrical contact with the enlarged electrode pads 25. Thus, the via 23 are “landed” on the respective enlarged electrode pads 25, in spite of their imperfect locations, and suitable electrical contacts are achieved between the elements 23 and 25. The enlarged electrode pads 25, however, can increase the separation 30 between the metallic lines 28 and can further increase the real-estate required for landing the via 23.

Turning to FIG. 2, the two metallic lines 28 in this figure are geometrically disposed in closer proximity to one another, compared to the metallic lines 28 of FIG. 1, as a consequence of reductions in feature sizes of the metallic lines 28. In particular, the enlarged electrode pads 25 have been reduced in size or removed from the metallic lines 28, to thereby achieve a separation distance 33 which is substantially less than the distance 30 of FIG. 1. Positioning of the via 23 directly onto the metallic lines 28 can facilitate relatively dense packing of the metallic lines 28 and, consequently, disposition of a larger number of metallic lines 28 and via 23 into the same wafer space.

Formation of the via 23 directly onto the metallic lines 28, however, can substantially increase the difficulty of aligning (i.e., landing) the via 23. It can be seen, for example, from a comparison of FIG. 1 with FIG. 2 that the difficulty of landing the via 23 increases as the sizes of the enlarged electrode pad 25 decrease. The occurrence of unlanded via conditions is typically associated with positioning of the via 23 beyond the bounds of the metallic lines 28, as shown in FIG. 2. Such unlanded via conditions are more prevalent when the via 23 are no smaller than, or only slightly smaller than, the respective metallic lines 28 to which they are connected.

FIG. 3 illustrates a mask-etching procedure wherein properly aligned via are generated on metallic lines without the assistance of enlarged electrode pads. In the figure, a metal layer 38, a titanium nitride (TiN) layer 40, and a silicon-oxy-nitride (SiON) layer 42 have been added on a substrate 35 and etched back to form lines. Subsequently, a high density plasma (HDP) layer 45 was deposited, followed by the application and patterning of a photoresist 47. The cross-sectional view of FIG. 4 illustrates the same wafer after the HDP deposited layer and SiON 42 have been etched to form via holes, the photoresist 47 has been removed, and the via holes have been filled with a via filler 49 such as tungsten to thereby form via.

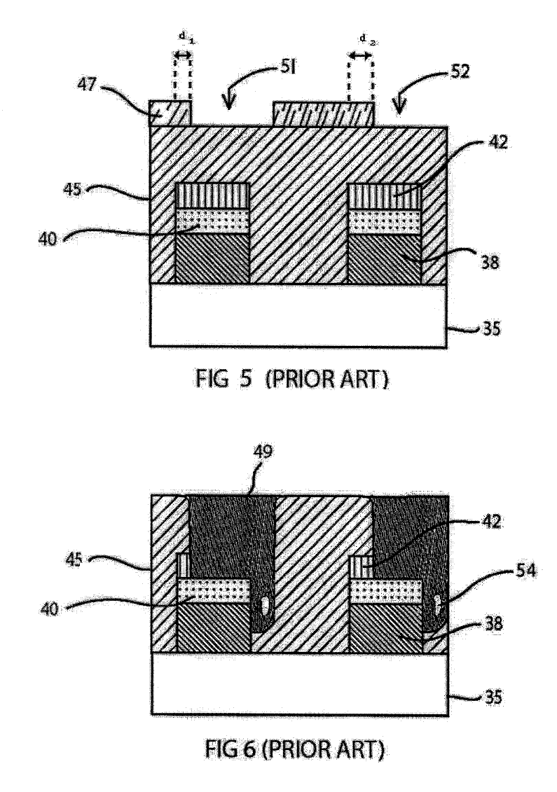

FIGS. 5 and 6 are substantially similar to FIGS. 3 and 4, with the difference being that the patterned photoresist 47 has been misaligned. Since the dimensions of the openings 51 and 52 in the patterned photoresist (which define the via) are very close to the boundaries defined by the metal lines 38, the tolerance for the positioning of the photoresist mask is very small. With particular reference to FIG. 5, the openings 51 and 52 in the patterned photoresist 47 are slightly shifted by distances d₁ and d₂, respectively, from their optimal positions. In practice, the distances d₁ and d₂ can have substantially the same values, or these distances may be divergent. In the illustrated example, the openings 51 and 52 are erroneously shifted the distances d₁ and d₂, respectively, to the right. When the via holes are subsequently etched as shown in FIG. 6, they will also be off-center or shifted by about the distances d₁ and d₂. Accordingly, portions of the via holes (i.e., “adverse structures”) will extend beyond the lines formed by the metal layer 38, resulting in unlanded via holes. In the illustrated example, during the etch process the sides of the lines formed by the metal layer 38 can be revealed as a result of the adverse structures.

After the via holes have been filled with via filler 49 to form via, small air gaps 54 can remain as a result of the adverse structures. These air gaps 54 can occur as a result of the via filler 49 having relatively poor step coverage in connection with filling the adverse structures of the via holes, and can be especially prevalent when the adverse structures extending beneath the TiN layer toward the substrate have relatively high aspect ratios.

Since unlanded via can be more prevalent when the enlarge electrode pads 25 are omitted, the present invention may have particular applicability to padless via architectures, wherein a padless via is defined herein to refer to a via having a diameter the same size as, or slightly smaller than, the width of the metallic lines (of metal layer 38) to which it is to be connected. The present invention can also have applicability to other types of via structures and applications, as well.

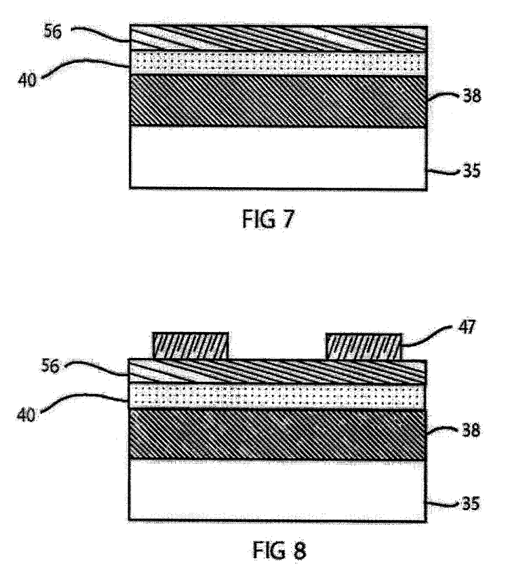

With reference to FIG. 7, a multi-layer thinfilm stack consisting from bottom to top of a substrate 35, a metal layer 38, a TiN layer 40, and a dyed SOG layer 56 layer is illustrated. Although the substrate 35 preferably comprises a silicon substrate, in alternative embodiments the substrate can comprise materials such as gallium nitride (GaN), gallium arsenide (GaAs), or other materials commonly recognized as suitable semiconductor materials to those skilled in the art. Initially, the substrate 35 is prepared prior to the metal layer 38 being sputtered onto the substrate. The metal layer 38 can comprise, for example, any highly conductive metal such as gold, aluminum, copper, or an alloy of a combination of aluminum and/or copper and other trace elements.

Next, a barrier material such as tantalum nitride (TaN), wolfram nitride (WN), molybdenum nitride (MoN), Ti/TiN, or TiN 40 is deposited by preferably by chemical vapor deposition (CVD). As used herein, Ti/TiN refers to either a titanium layer which has been annealed in a nitrogen atmosphere to at least partially convert the titanium to titanium nitride, or a thin titanium layer on which is deposited a thin TiN layer by a separate process step. In the illustrated embodiment the TiN layer 40 is deposited as the barrier material, being a hard, dense, refractory material which can provide high electrical conductivity. The TiN layer 40 further acts as an ARC, thus inhibiting undesirable reflectance from the metal layer 38 and facilitating better resolution in the alignment of a photoresist mask to existing structures or alignment marks. The TiN layer 40 can further minimize the occurrence of standing waves when using a stepper to thereby attenuate exposure problems, and can also serve as a lower etch stop to reduce risks of etching into the metal layer 38. Furthermore, as presently embodied, the TiN layer 40 can help to prevent reaction between the metal layer 38 and a via filler 60 (FIG. 14).

In accordance with the present invention, a rapid-etch material is then applied. As presently embodied, the rapid-etch material comprises a rapid-etch dielectric that can be etched at a faster rate than a competing dielectric material, such as the HDP deposited layer 45 shown in FIG. 11. In a presently preferred embodiment, the rapid-etch dielectric comprises a dyed SOG which is spun onto the TiN layer 40. The dyed SOG can comprise, for example, a methyl siloxane, ethyl siloxane, and/or siloxene polymer material, which incorporates a dye chosen for example to enhance the etch rate of the dyed SOG for an etchant, compared to an etch rate of a competing dielectric for the etchant.

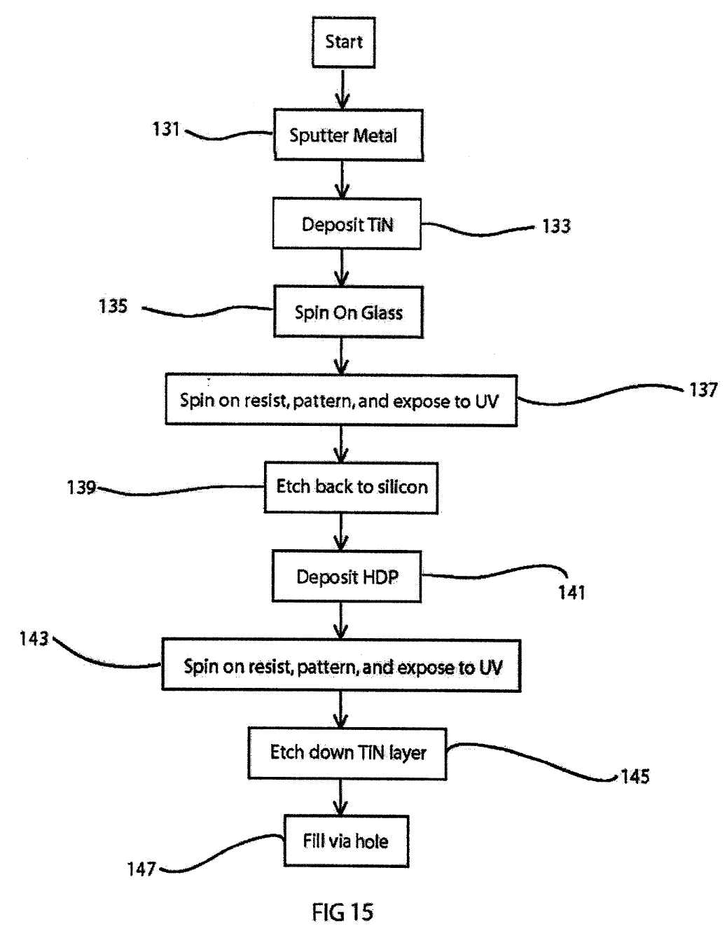

Furthermore, the dyed SOG layer 56 can act to minimize, for example, standing waves within the film stack, thus allowing for a more controllable exposure within the stepper. Additionally, undesirable changes in substrate (e.g., TiN layer 40) reflectivity which can conventionally occur during the via hole etching step 145 (FIG. 15) can be attenuated as a consequence of the dyed SOG. Consequently, the thickness of the TiN layer 40 (having a relatively high resistivity) can be reduced or eliminated in certain applications without sacrificing performance, to thereby provide a higher-conductivity path through the via. In alternative embodiments, the SOG layer or the dyed SOG layer 56 can act as a hard mask during the metal layer 38 etch process described above with reference to FIGS. 7-10, and, consequently, the thickness of the photoresist layer 47 can be effectively reduced to prevent the collapse of the photoresist layer. This application can be especially beneficial in the context of decreasing dimensions of semiconductor devices.

FIG. 8 shows a cross-sectional view of the wafer of FIG. 7 modified by the addition of a patterned layer of photoresist 47. As is common in the art, the layer of photoresist 47 is first spun onto the wafer. The wafer is then placed into a stepper (photolithography tool for patterning wafers) where it is aligned to a mask and exposed to ultra violet (UV) radiation. The mask may only be large enough to cover a small portion of the wafer, in which case the stepper steps the wafer through many quadrants, each of them being exposed in turn, until the entire or desired portion of wafer has been exposed to UV light. The wafer is then placed into a chemical bath that dissolves the photoresist 47 which was exposed to the UV radiation, to thereby yield the patterned photoresist layer 47.

Next the wafer is positioned within a dry etcher, where it is etched anisotropically. The etchant is preferably unreactive to the photoresist 47 while it etches the dyed SOG layer 56, the TiN layer 40, and the metal layer 38 at varying rates. As presently embodied, the wafer is etched for a time sufficient to completely remove any residual metal 38 from the substrate 35 in the exposed areas.

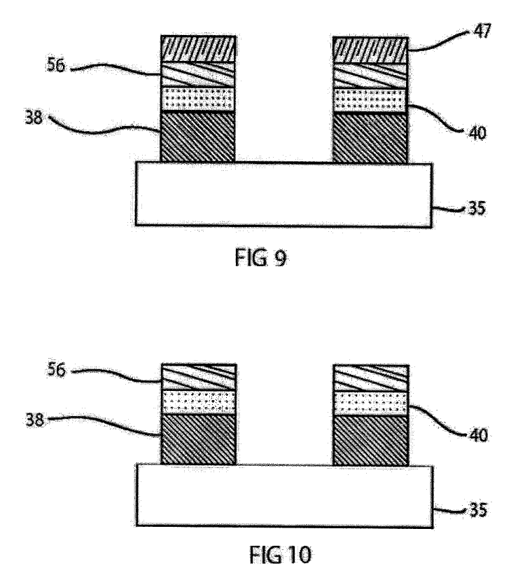

FIG. 9 illustrates the resulting structure after exposed parts of the dyed SOG layer 56, the TiN layer 40, and the metal layer 38 have been etched down to the silicon substrate 35. The resulting structure thus includes metallic lines 28 (FIG. 2) formed by the metal layer 38 remaining within first boundaries over covered portions of the substrate 35, and further includes uncovered portions within second boundaries on the substrate 35 that have been etched.

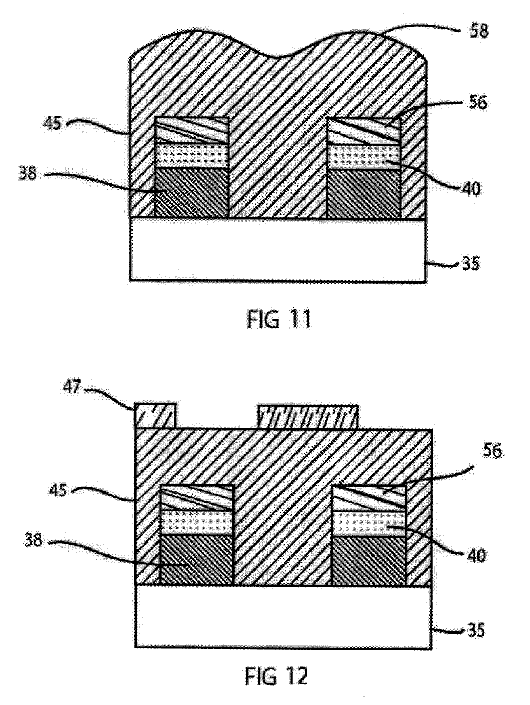

In a subsequent processing step, the wafer is placed into a chemical bath solution which removes the remaining patterned photoresist mask 47. A cross-sectional view of the wafer after the photoresist has been removed is shown in FIG. 10.

The following processing step involves the deposition of a dielectric layer onto the substrate 33. As presently embodied, the dielectric layer can comprise silicon dioxide (SiO₂) formed by a HDP CVD application. This layer will be referred to simply as the HDP deposited layer 45. FIG. 11 provides a cross-sectional view of the wafer wherein the HDP deposited layer 45 has been formed on the exposed surface topography, filling between the metallic lines and creating a layer of insulation between the current metal layer and any following metal layers.

Since in the illustrated embodiment the HDP deposited layer 45 is not deposited on a flat surface, it can inherently have surface contours 58. These contours 58 can create obstacles or steps which render it difficult to spin on the subsequent photoresist 47 evenly. Therefore, as presently embodied the wafer undergoes a process commonly referred to as chemical mechanical planarization (CMP) to create a relatively flat surface. As known to those having skill in the semiconductor processing art, CMP is an abrasive process performed on oxides and metals that is used to polish the surface of the wafer flat. Chemical slurries can be used along with a circular “sanding” action to create a smooth polished surface. This smooth surface may be necessary, for example, to maintain a proper depth of focus for subsequent steps in the stepper, and can also ensure that the via are not deformed over contour steps.

After the planarization process, another layer of photoresist 47 is spun on, patterned, and exposed to UV radiation to yield the configuration shown in FIG. 12. When the photoresist layer 47 is patterned using a via mask, care should be taken to ensure that the via-mask is properly aligned. To the extent misalignment is present, unlanded via holes may occur in which case the processes and structures of the present invention can operate to attenuate any adverse side-affects which may be introduced therefrom. Namely, when the via holes are anisotropically dry etched the etching rates of the HDP deposited layer 45 and the rapid-etch dielectric 56 are engineered in accordance with the present invention to attenuate or eliminate adverse via structures which may result from the misalignment.

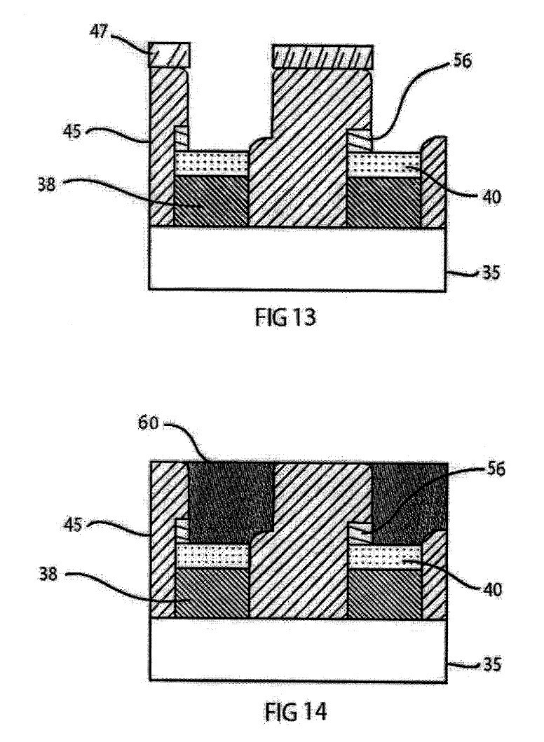

The inventive construction illustrated in FIG. 13 shows via holes which have been successfully etched, relative to prior-art implementations, in spite of the presence of an unlanded via hole condition. Each unlanded via hole extends partially over a corresponding metal line 38 and partially over a portion of the substrate 35 covered by the HDP deposited layer 45. The landed portion of each unlanded via hole contacts a first region of a corresponding TiN 40 line, while a remaining portion of the rapid-etch layer 56 sits on a second region of each corresponding TiN 40 line. In particular, the occurrence of adverse structures associated with unlanded portions of the via holes has been attenuated and, preferably, eliminated. Since, according to the present invention, the dyed SOG layer 56 is etched more quickly than the HDP deposited layer 45, side portions of the metal layer 38 are advantageously not exposed. In comparison, the prior-art implementation of FIG. 5 incorporates a slower-etching SiON layer 42. Thus, in order to create a clean TiN layer 40 in the presence of an unlanded via hole, the FIG. 5 implementation will almost inevitably etch down to and expose the side wall of the metal layer 38, thereby creating an adverse structure.

A via filler 60 is then applied into the etched via holes, as shown in FIG. 14. In accordance with the present invention, the presence of air gaps 54 has been reduced and, preferably, eliminated. Accordingly, as can be seen in the figure, many of the negative effects of the unlanded via including adverse structures have been eliminated. Regarding application of the via filler 60, the filler may include a conductive material such as tungsten, which is applied by physical vapor deposition (PVD) or sputtering or, alternatively, CVD into the via holes. As presently embodied, a Ti/TiN barrier layer (not shown) is applied into the etched via holes before application of the tungsten. Alternatively, other Ti, Ti composite or other materials with similar properties may be used to form the barrier layer. In cases where the tungsten has a tendency to peel back, the Ti/TiN barrier layer can be deposited into the etched via holes as an adhesive layer for preventing peeling or loosening of the tungsten.

The Ti/TiN layer may be applied over the sidewalls and bottom of the etched via holes to assure good adhesion of the via filler material 60, and further to prevent spiking and electromigration. The bottom liner of Ti/TiN can provide additional protection from reactions between the via filler material 60 and the metal line 38, in an event wherein the via etch penetrates through both the rapid-etch dielectric 56 and the TiN layer 40. Although effective as a safety measure, the Ti/TiN layer at the bottom of the etched via hole can add additional resistance to the via structure. Accordingly, in a preferred embodiment the Ti/TiN layer is formed to have a relatively small thickness.

FIG. 15 shows a flow chart of the process for creating via using a rapid-etch material, such as dyed SOG, in accordance with the present invention. A metal layer 38 is initially sputtered onto a prepared substrate 35, which preferably comprises silicon, at Step 131. At Step 133 a layer of TiN 40 is deposited onto the metal layer 38 using CVD. Following deposition of the metal layer 38, a layer of rapid-etch material 56, which preferably comprises dyed SOG, is deposited at Step 135 onto the substrate 35 over the TiN layer 40. At Step 137 a photoresist 47 is spun on, patterned, and exposed to UV radiation. The remaining patterned photoresist 47 is then dissolved in a chemical bath and removed. During a subsequent etching process shown at Step 139, exposed portions not protected by photoresist of the metal layer 38, the TiN layer 40, and the rapid-etch layer 56 are etched back to the substrate 33. A dielectric layer 45 is then deposited with HDP CVD at Step 141 to thereby cover all exposed geographic features. At Step 143, photoresist 47 is spun on, patterned, and exposed to UV radiation, followed by a sub-step of dissolving and removing the exposed photoresist 47 by means of a chemical bath.

The HDP deposited dielectric layer 45 and the rapid-etch layer 56 are then etched down to the TiN layer 40 at Step 145 using, in a preferred embodiment, an anisotropic dry etcher. In accordance with the present invention, the rapid-etch material 56, the dielectric layer 45, and the etchant of Step 145 are all selected so that the rapid-etch material 56 will be etched in Step 145 at a sufficiently rapid rate, relative to a rate at which the dielectric layer 45 is etched by the etchant, to avoid the formation of adverse structures (when unlanded via are introduced by way of, for example, photoresist mask misalignment at Step 143). An adverse structure associated with an unlanded via can include the unlanded portion of the via extending down past the TiN layer 40 and exposing part of the metal layer 38 as shown in FIG. 6. As corrected by the present invention, however, the rapid-etch material 56 is etched at a rate sufficient to facilitate conclusion of the via hole etch, before the dielectric layer 45 at the side of the TiN layer (as distinguished from “on” the TiN layer) is etched down below a level of the TiN layer. Etch-rate characteristics of the materials 45 and 56 can be varied by choosing materials based on their selectivities (i.e., etching rates) to an etchant, or by other means such as by implementing various etching processes to control the etching rates of the materials. Accordingly, adverse structures associated with the unlanded via can be avoided with the methods of the present invention.

In accordance with one feature of the present invention, a ratio of the etch rate of the rapid-etch material 56 to the etchant, compared to the etch rate of the dielectric layer 45 to the etchant, should be sufficient to facilitate completion of the via hole etch before adverse structures are formed. Such desired etch rates can be achieved when using etchants such as trifluoromethane (CHF3), carbon tetrafluoride (CF4), and oxygen (O2). Tolerances for various sizes, aspect ratios, and extents of adverse structures may vary depending on the application. For example, in low cost or non-critical applications adverse structures may be tolerated to some extent, while in other applications higher quality circuits are mandated. Thus, in certain applications the ratio may vary from, for example, about 1 on up, while in other applications and as presently preferred the ratio should be greater than 1 and, more preferably, greater than 1.5. In the illustrated embodiment, the ratio should be between about 1.5 and about 2. Finally, at Step 147, the via hole is filled with a via filler 60, such as tungsten, to form a via.

Although the present invention can have particular applicability to padless via, the present invention should not be limited to such structures. For example, the rapid-etch material layers 56 of the present invention may optionally be used in connection with via formed on padded metallic lines such as shown in FIG. 1. In such applications, even if adverse structures resulting from etching along the sides of a metallic line are not issues of concern, it can still be advantageous to use the rapid-etch layers 56 of the present invention. Since the rapid-etch material layers 56 (e.g., dyed SOG) etch more quickly than SiON 42, for example, processing time can be reduced. Furthermore, to the extent that the rapid-etch layer 56 can be used in place of SiON in certain applications, inventories and equipment associated with SiON can be reduced, and set-up time otherwise consumed by switching between SOG and SiON may commensurately be reduced. For example, to the extent the inventive rapid-etch materials are used with padless via circuits, it may make economical sense to run the manufacturing processes for padded via circuits with the same material in place of SiON. Also, designers who wish to have both padded and unpadded via could use dyed SOG 56 for both, rather than having to resort to SiON 42 for the padded via. Finally, with use of the inventive rapid-etch material layer 56 even with padded via circuits, should an unlanded via ever occur, the resulting adverse structures can be attenuated or eliminated.

In view of the foregoing, it will be understood by those skilled in the art that the methods of the present invention can facilitate formation of operational unlanded via in integrated circuits. The above-described embodiments have been provided by way of example, and the present invention is not limited to these examples. Multiple variations and modification to the disclosed embodiments will occur, to the extent not mutually exclusive, to those skilled in the art upon consideration of the foregoing description. For example, the rapid-etch layer can comprise SOG instead of dyed SOG, in which case the TiN layer can be primarily or entirely responsible for minimizing standing waves in the film stack during the lithography process. Such variations and modifications, however, fall well within the scope of the present invention as set forth in the following claims.

What is claimed is:

1. A method comprising the following steps:
providing a substrate with a conductive layer formed thereon;
depositing a spin on glass (SOG) layer;
defining a plurality of conductive lines in connection with a first etching step;
depositing a dielectric layer; and
defining at least one via hole in connection with a second etching step.

2. The method as set forth in claim 1, wherein the SOG layer is a dyed SOG layer.

3. The method as set forth in claim 1, wherein:
the at least one via hole comprises a plurality of via holes;
an anti-reflective coating (ARC) layer is formed between the conductive layer and the SOG layer; and
the step of depositing a dielectric layer comprises a step of depositing a dielectric layer by HDP chemical vapor deposition (CVD); and
the plurality of via holes are filled with a conductive material to form a plurality of via.

4. A method comprising the following steps:
providing a substrate with a conductive layer formed thereon;
depositing a rapid-etch dielectric layer;
defining a plurality of conductive lines in association with a first etching step;
depositing another dielectric layer; and
defining at least one via hole in association with a second etching step in which the rapid-etch dielectric layer is etched at a higher rate than a rate at which the other dielectric layer is etched.

5. The method as set forth in claim 4, wherein:
the second etching step is performed with an etchant; and
an etch rate of the rapid-etch dielectric layer to the etchant is about 1.5 to about 2 times greater than an etch rate of the other dielectric layer to the etchant.

6. The method as set forth in claim 4, wherein:
the step of defining at least one via hole comprises a step of defining a plurality of via holes and is followed by a step of filling the via holes with a conductive material to form a plurality of via;
the step of depositing a rapid-etch dielectric layer comprises a step of depositing a dyed spin on glass (SOG) layer; and
the step of depositing another dielectric layer comprises a step of a depositing a dielectric layer by high density plasma (HDP) chemical vapor deposition (CVD).

7. A structure, comprising:
a plurality of conductive lines extending on covered portions of a substrate but not extending on uncovered portions of the substrate;
a rapid-etch material positioned over regions of the plurality of conductive lines;
a dielectric material disposed over at least parts of the covered portions and the uncovered portions; and
a plurality of via holes etched into the dielectric material using an etchant, wherein an etch rate of the rapid-etch material for the etchant is greater than an etch rate of the dielectric material for the etchant.

8. The structure as set forth in claim 7, wherein:
the structure further comprises a plurality of anti-reflective coating (ARC) lines disposed on the plurality of conductive lines;
the rapid-etch material is positioned on the ARC lines;
the dielectric material is disposed above parts of the covered portions and on the uncovered portions; and
the plurality of via holes are disposed on first regions of the ARC lines.

9. The structure as set forth in claim 8, wherein:
the rapid-etch material comprises a dielectric material disposed on second regions of the ARC lines; and
the first regions of the ARC lines are not the same as the second regions of the ARC lines.

10. The structure as set forth in claim 9, wherein:
the ARC lines comprises titanium nitride (TiN); and
the via holes are filled with a conductive material to form via.

11. The structure as set forth in claim 9, wherein the rapid-etch material comprises dyed spin on glass (SOG).

12. A structure, comprising:
a substrate;
a plurality of conductive lines extending within corresponding first boundaries of the substrate but not extending within second boundaries of the substrate;
a material covering at least portions of the conductive lines; and
a plurality of via holes formed at least partially within the material and overlapping both the first boundaries and the second boundaries, wherein parts of the plurality of via holes overlapping the second boundaries do not extend in directions toward the substrate as far as parts of the plurality of via holes overlapping the first boundaries.

13. The structure as set forth in claim 12, wherein:
the plurality of via holes are filled with a conductive material to form a plurality of via; and
the structure further comprises a rapid-etch material disposed over at least parts of the plurality of conductive lines.

14. The structure as set forth in claim 13, wherein:
the structure further comprises a plurality of anti-reflective coating (ARC) lines disposed on the plurality of conductive lines, the plurality of ARC lines being at least partially sandwiched between the plurality of via and the plurality of conductive lines;
the rapid-etch material comprises a dielectric material; and
the rapid-etch material covers portions of the plurality of conductive lines that exclude the first boundaries overlapped by the plurality of via.

15. The structure as set forth in claim 13, wherein the rapid-etch material comprises dyed spin on glass (SOG).

16. A structure, comprising:
a substrate having at least one conductive line disposed thereon;
a material covering at least part of the at least one conductive line;
a rapid-etch layer disposed over a first portion of the at least one conductive line; and
at least one via hole formed at least partially in the material over a second portion of the at least one conductive line;
wherein the first portion of the at least one conductive line is not the same as the second portion of the at least one conductive line; and
wherein the at least one via hole does not extend, in a direction toward the substrate, beneath an upper surface of the at least one conductive line.

17. The structure as set forth in claim 16, wherein:
the structure further comprises at least one anti-reflective coating (ARC) line disposed on the at least one conductive line; and
the at least one via hole does not extend, in a direction toward the substrate, beneath an upper surface of the at least one ARC line.

18. The structure as set forth in claim 17, wherein:
the material comprises a dielectric deposited by high density plasma (HDP) chemical vapor deposition (CVD);
the at least one conductive line comprises at least one metal line; and
the at least one ARC line comprises titanium nitride (TiN).

19. The structure as set forth in claim 16, wherein:
the at least one conductive line comprises a plurality of conductive lines;
the at least one via hole comprises a plurality of via holes;
the first portion of the at least one conductive line comprises a plurality of first portions of a corresponding plurality of conductive lines; and
the second portion of the at least one conductive line comprises a plurality of second portions of a corresponding plurality of conductive lines.

20. The structure as set forth in claim 19, wherein:
the plurality of via holes are filled with a conductive material to form a plurality of via; and
the rapid-etch layer comprises a spin on glass (SOG) layer.

21. The structure as set forth in claim 16, wherein:
the at least one via hole is formed using an etchant; and
an etch rate of the rapid-etch layer to the etchant is at least about 1.5 to about 2 times greater than an etch rate of the material to the etchant.

22. The structure as set forth in claim 16, wherein:
the at least one via hole is formed using an etchant; and
an etch rate of the rapid-etch layer to the etchant is at least about 1.5 times greater than an etch rate of the material to the etchant.
